(19) United States
(12) Patent Application Publication
(10) Pub. No.: US 2011/0233513 A1
(43) Pub. Date: Sep. 29, 2011

(54) ENHANCED BONDING INTERFACES ON CARBON-BASED MATERIALS FOR NANOELECTRONIC DEVICES

(75) Inventors: Christos D. Dimitrakopoulos, Baldwin Place, NY (US); Damon B. Farmer, White Plains, NY (US); Alfred Grill, White Plains, NY (US); Stephen M. Gates, Ossining, NY (US); Tuan A. Vo, Albany, NY (US); Deborah A. Neumayer, Danbury, CT (US); Son Van Nguyen, Schenectady, NY (US)

(73) Assignee: INTERNATIONAL BUSINESS MACHINES CORPORATION, Armonk, NY (US)

(21) Appl. No.: 12/748,542

(22) Filed: Mar. 29, 2010

(51) Int. Cl. H01L 29/16; H01L 21/04; C30B 23/02

(52) U.S. Cl. 257/9; 438/591; 117/108; 257/E29.082; 257/E21.051; 977/742

(57) ABSTRACT

Semiconductor structures and electronic devices are provided that includes at least one layer of an interfacial dielectric material located on an upper surface of a carbon-based material. The at least one layer of interfacial dielectric material has a short-range crystallographic bonding structure, typically hexagonal, that is the same as that of the carbon-based material and, as such, the at least one layer of interfacial dielectric material does not change the electronic structure of the carbon-based material. The presence of the at least one layer of interfacial dielectric material having the same short-range crystallographic bonding structure as that of the carbon-based material improves the interfacial bonding between the carbon-based material and any overlying material layer, including a dielectric material, a conductive material or a combination of a dielectric material and a conductive material. The improved interfacial bonding in turn facilitates formation of devices including a carbon-based material.

### BACKGROUND

The present invention relates to a semiconductor structure and a method of fabricating the same. More particularly, the present invention relates to a semiconductor structure including at least one layer of an interfacial dielectric material located on an upper surface of a carbon-based material. The at least one layer of interfacial dielectric material that is in contact with the upper surface of the carbon-based material has at least the same short-range crystallographic bonding structure as the crystallographic bonding structure of the carbon-based material. The present invention also provides a method of forming such a semiconductor structure as well as electronic devices built upon the semiconductor structure.

Several trends presently exist in the semiconductor and electronics industry including, for example, devices are being fabricated that are smaller, faster and require less power than the previous generations of devices. One reason for these trends is that personal devices such as, for example, cellular phones and personal computing devices, are being fabricated that are smaller and more portable. In addition to being smaller and more portable, personal devices also require increased memory, more computational power and speed. In view of these ongoing trends, there is an increased demand in the industry for smaller and faster transistors used to provide the core functionality of the integrated circuits used in these devices.

Accordingly, in the semiconductor industry there is a continuing trend toward fabricating integrated circuits (ICs) with higher densities. To achieve higher densities, there has been, and continues to be, efforts toward down scaling the dimensions of the devices on semiconductor wafers generally produced from bulk silicon. These trends are pushing the current technology to its limits. In order to accomplish these trends, high densities, smaller feature sizes, smaller separations between features, and more precise feature shapes are required in integrated circuits (ICs).

Significant resources go into down scaling the dimensions of devices and increasing packing densities. For example, significant time may be required to design such down scaled transistors. Moreover, the equipment necessary to produce such devices may be expensive and/or processes related to producing such devices may have to be tightly controlled and/or be operated under specific conditions. Accordingly, there are significant costs associated with exercising quality control over semiconductor fabrication.

In view of the above, the semiconductor industry is pursuing graphene to achieve some of the aforementioned goals. Graphene, which is essentially a flat sheet of carbon atoms, is a promising material for radio frequency (RF) transistors and other electronic transistors. Typical RF transistors are made from silicon or more expensive semiconductors such as, for example, indium phosphide (InP). In graphene, and for the same voltage, electrons travel around 10 times faster than in InP, or 100 times faster than in silicon. Graphene transistors will also consume less power and could turn out to be cheaper than those made from silicon or InP.

Graphene electronic devices operating at 26 gigaHertz have been fabricated and the ultimate graphene device operating performance is expected to be in the tetraHertz range. However, building such graphene devices is generally difficult to achieve. One reason for this difficulty is that the bonding between graphene and other materials, e.g., dielectric materials and/or conductive materials, is difficult due to the graphene changing electronic structure and properties when a bonding interface is created.

### SUMMARY

In one aspect of the present disclosure, a semiconductor structure is provided that includes at least one layer of an interfacial dielectric material located on an upper surface of a carbon-based material. The at least one layer of interfacial dielectric material has at least the same short-range crystallographic bonding structure as that of the carbon-based material and, as such, the at least one layer of interfacial dielectric material, that is in contact, does not change the electronic structure of the carbon-based material. The term “short-range order” as used throughout the present application denotes that the interfacial dielectric material can be composed of a mixture of partially amorphous and hexagonal bonding phases. In one embodiment, the interfacial dielectric has the same crystallographic bonding structure as that of the carbon-based material. In a further embodiment, the interfacial dielectric and the carbon-based material both have a hexagonal crystallographic bonding structure.

Moreover, the at least one layer of interfacial dielectric material is bonded to the carbon-based material via van der Waals forces. By ‘van der Waals’ forces it meant the process by which molecules are attracted to each other, via electrostatic forces. These intermolecular attractions are weaker than both ionic and covalent bonding. Bonding through the van der Waals forces occurs through dipole interactions. Dipolar molecules are the types of molecules involved in this type of bonding. In dipolar molecules, the electronegativity difference between the covalently bonded atoms exceeds or equals 0.4 but is less than or equal to 2.0. This difference in electronegativity causes the electrons of the molecule to become unequally distributed. The atoms within the molecule that have the higher electronegativity attract the electrons from those with less electronegativity. The atoms with the higher electronegativity acquire a slightly negative charge, denoted by δ⁻. The atoms with less electronegativity acquire a slightly positive charge, denoted by δ⁺. These regions of the molecules are magnetically attracted to the oppositely charged regions of other dipolar molecules. In this way, the dipolar molecules are bonded to one another, and it is this bonding that constitutes van der Waals bonding.

The presence of the at least one layer of interfacial dielectric material having at least the same short-range crystallographic bonding structure as that of the carbon-based material improves the interfacial bonding between the carbon-based material and any overlying material layer, including a dielectric material, a conductive material or a combination of a dielectric material and a conductive material. The improved interfacial bonding, in turn, facilitates formation of devices including a carbon-based material as an active element of the device.

In one embodiment of the invention, the carbon-based material is graphene and the interfacial dielectric material is hexagonal boron nitride. Applicants observe that graphene and boron nitride both have a hexagonal crystallographic bonding structure, and that low temperature amorphous boron nitride and/or carbon boron nitride have some of the same short-range hexagonal crystallographic bonding like graphene, and, as such can be employed herein. Moreover, graphene has a similar bonding length (C—C bond length of 1.42 Å) to pure hexagonal boron nitride (B—N bond length of 1.43 Å).

In another aspect of the present disclosure, an electronic device such as, for example, a transistor, including the aforementioned semiconductor structure is provided. In particular, the present invention provides, in one embodiment, an electronic device that includes a carbon-based material, wherein a portion of the carbon-based material defines a device channel. The electronic device further includes at least one layer of an interfacial dielectric material located on an upper surface of the device channel, wherein the at least one layer of interfacial dielectric material has at least the same short-range crystallographic bonding structure as that of the carbon-based material. In one embodiment, the at least one layer of interfacial dielectric material has the same crystallographic bonding structure as that of the carbon-based material. The electronic device still further includes at least one layer of a dielectric material located on an uppermost surface of the at least one layer of interfacial dielectric material, and at least one layer of a conductive material located on an uppermost surface of the at least one layer of dielectric material. The electronic device even further includes at least two regions making electrical contact to portions of the carbon-based material that are adjacent to the device channel.

In still another aspect of the present disclosure, a method of providing the above mentioned semiconductor structure is provided. The method of the present disclosure includes forming at least one layer of an interfacial dielectric material on an upper surface of a carbon-based material, wherein the at least one layer of interfacial dielectric material has at least the same short-range crystallographic bonding structure as that of the carbon-based material. In one embodiment, the at least one layer of interfacial dielectric material has the same crystallographic bonding structure as that of the carbon-based material. The aforementioned method can be integrated into any existing FET process flow.

### BRIEF DESCRIPTION OF SEVERAL VIEWS OF THE DRAWINGS

FIG. 1 is a pictorial representation (though a cross sectional view) illustrating an initial structure including a carbon-based material that can be employed in one embodiment of the present invention.

FIG. 2 is a pictorial representation (though a cross sectional view) illustrating the initial structure of FIG. 1 after forming an interfacial dielectric material layer having at least the same short-range crystallographic bonding structure as the carbon-based material an upper surface of the carbon-based material.

FIG. 3 is a pictorial representation (though a cross sectional view) illustrating the structure of FIG. 2 after forming at least one material layer (dielectric and/or conductive) atop the interfacial dielectric material layer.

FIG. 4 is a pictorial representation (through a cross sectional view) illustrating an electronic device, e.g., a transistor, on the structure shown in FIG. 2 in accordance with an embodiment of the present invention.

FIG. 5 is a pictorial representation (through a cross sectional view) illustrating another electronic device, e.g., a transistor, on the structure shown in FIG. 2 in accordance with another embodiment of the present invention.

### DETAILED DESCRIPTION

In the following description, numerous specific details are set forth, such as particular structures, components, materials, dimensions, processing steps and techniques, in order to provide an understanding of some aspects of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Embodiments of the present invention will now be described in greater detail by referring to the following discussion and drawings that accompany the present application. The drawings of the present application, which are referred to herein below in greater detail, are provided for illustrative purposes and, as such, they are not drawn to scale.

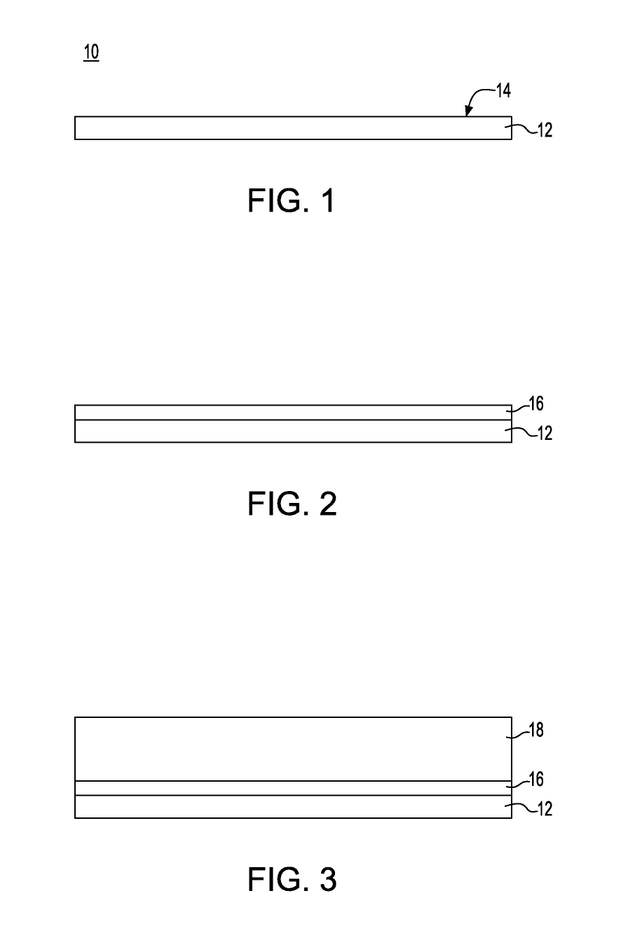

Reference is first made to FIGS. 1-3 which illustrate the basic processing steps that can be employed in one embodiment of the present invention. Specifically, FIG. 1 illustrates an initial structure 10 that can be employed in one embodiment of the present invention. The initial structure 10 includes at least a carbon-based material 12 which has a bare upper surface 14. Although not shown in the drawings, the carbon-based material 12 can be located atop a base substrate which can be a semiconductor material, a dielectric material, a conductive material or any combination thereof including a multilayered stack.

The term ‘semiconductor material’ denotes any material that has semiconductor properties. Examples of semiconductor materials that can be located beneath the carbon-based material 12 include, but are not limited to Si, SiGe, SiGeC, SiC, Ge alloys, GaAs, InAs, InP, BN and other III/V or II/VI compound semiconductors. In addition to these listed types of semiconductor materials, the semiconductor material that can be present beneath the carbon-based material 12 can also be a layered semiconductor such as, for example, Si/SiGe, Si/SiC, silicon-on-insulators (SOIs) or silicon germanium-on-insulators (SGOIs), BN and other III/V or II/VI compound semiconductors. In some embodiments of the invention, the semiconductor material beneath the carbon-based material 12 is a Si-containing semiconductor material, i.e., a semiconductor material that includes silicon. The semiconductor material that can be employed beneath the carbon-based material 12 can be single crystalline, polycrystalline, multicrystalline, and/or hydrogenated-amorphous. The semiconductor materials that can be employed beneath the carbon-based material 12 can be undoped, doped or contain doped and undoped regions therein.

The dielectric material that can be located beneath the carbon-based material 12 includes any material having insulator properties. Examples of dielectric materials that can be located beneath the carbon-based material 12 include, but are not limited to glass, SiO₂, SiN, plastic, or diamond-like carbon, BN, CₓBN or a mixture of amorphous/hexagonal bonding boron nitride and carbon boron nitride.

The conductive material that can be located beneath the carbon-based material 12 includes any material having electrical conductive properties. Examples of such conductive materials include, but are not limited to a metal, or a transparent conductor including, for example, a metal oxide or other conductive forms of carbon.

In one embodiment of the invention, the carbon-based material 12 shown in FIG. 1 includes at least one layer of graphene. The term “graphene” is used herein to denote a one-atom-thick planar sheet of sp²-bonded carbon atoms that are densely packed in a honeycomb crystal lattice. The graphene employed in the invention has a hexagonal crystallographic bonding structure. The graphene that can be employed in the present disclosure can be comprised of single-layer graphene (nominally 0.34 nm thick), few-layer graphene (2-10 graphene layers), multi-layer graphene (>10 graphene layers), a mixture of single-layer, few-layer, and multi-layer graphene, or any combination of graphene layers mixed with amorphous and/or disordered carbon phases. The graphene employed in the present invention can also include, if desired, substitutional, interstitial and/or intercalated dopant species as well.

The graphene that can be used as the carbon-based material 12 can be formed utilizing techniques that are well known in the art. For example, the graphene that can be employed as the carbon-based material 12 can be formed by mechanical exfoliation of graphite, epitaxial growth on silicon carbide, epitaxial growth on metal substrates, hydrazine reduction in which a graphene oxide paper is placed in a solution of pure hydrazine which reduces the graphene oxide paper into single-layered graphene, and sodium reduction of ethanol, i.e., by the reduction of ethanol by sodium metal, followed by pyrolysis of the ethoxide product and washing to remove sodium salts. Another method of forming graphene can be from carbon nanotubes.

In another embodiment of the present invention, the carbon-based material 12 includes at least one carbon nanotube, which can be single walled or multiwalled. The carbon nanotubes employed in the present invention typically have a folded hexagonal crystallographic bonding structure. Although a single carbon nanotube can be used in the present invention, an array of carbon nanotubes is typically used. When carbon nanotubes are employed in the present invention as carbon-based material 12, the carbon nanotubes can be formed utilizing techniques that are well known to those skilled in the art for forming the same. Examples of suitable techniques that can be used in forming carbon nanotubes include, but are not limited to arc discharge, laser ablation, chemical vapor deposition, and plasma enhanced chemical vapor deposition. Other possible carbon-based materials that can be employed include graphite with a short-range hexagonal and amorphous crystallographic bonding structure and various forms of carbon materials with a slightly distorted hexagonal crystallographic bonding structure, such as, for example, Lonsdaleite or densely packed hexagonal bonding phase fullerene.

Notwithstanding the type of carbon-based material 12 employed in the present invention, the carbon-based material 12 can be orientated parallel to an underlying substrate, or perpendicular to an underlying substrate. A parallel oriented carbon-based material 12 is shown in the drawings of the present application by way of one possible orientation for the carbon-based material 12.

The thickness of the carbon-based material 12 can vary depending on the type of carbon-based material 12 employed as well as the technique that was employed in forming the same. Typically, and in one embodiment of the invention, the carbon-based material 12 has a thickness from 0.2 nm to 10 nm, with a thickness from 0.34 nm to 3.4 nm being more typical. Other thicknesses besides those mentioned can also be employed in the present invention.

Referring now to FIG. 2, there is illustrated the structure of FIG. 1 after forming at least one layer of an interfacial dielectric material 16 on the bare upper surface 14 of the carbon-based material 12. The at least one layer of the interfacial dielectric material 16 can be a single layer or multiple layers. In one embodiment, the at least one layer of the interfacial dielectric material 16 includes from 1 to 4 layers of interfacial dielectric material.

The at least one layer of the interfacial dielectric material 16 is a thin layer, whose thickness is typically from 0.2 nm to 10 nm, with a thickness from 0.3 nm to 3 nm being more typical. The at least one layer of the interfacial dielectric material 16 that is formed on the bare upper surface 14 of the carbon-based material 12 has a short-range crystallographic bonding structure, typically hexagonal, that is similar to the crystallographic bonding structure of the carbon-based material 12. Moreover, the at least one layer of the interfacial dielectric material 16 is bonded to the bare upper surface 14 of the carbon-based material 12 by van der Waals forces. By ‘van der Waals’ forces it meant the process by which molecules are attracted to each other, via electrostatic forces. No other type of bonding, such as ionic or covalent, is present at the interface between the carbon-based material 12 and the at least one layer of the interfacial dielectric material 16.

The type of the at least one layer of the interfacial dielectric material 16 that is employed in the present invention is dependent on the crystallographic bonding structure of the underlying carbon-based material 12. For example, when the underlying carbon-based material 12 has a hexagonal bonding crystallographic bonding structure, then the interfacial dielectric material 16 employed in the present invention also has a short-range hexagonal crystallographic bonding structure. Examples of interfacial dielectric materials that have a short-range hexagonal bonding crystallographic bonding structure and thus can be employed in one embodiment of the invention include, but are not limited to hexagonal boron nitride or a mixture of amorphous and hexagonal bonding boron nitride and carbon boron nitride.

Other interfacial dielectric materials that can be used include, but are not limited to SiC, SiBN, SiCBN that have an amorphous phase, with some hexagonal bonding phase mixed therein. These materials have similar crystallographic hexagonal bonding like hexagonal boron nitride.

The above combination of various carbon-based materials and the suitable short-range hexagonal crystallographic bonding can be used in combination to produce working electronic devices.

The at least one layer of the interfacial dielectric material 16 can be formed utilizing conventional deposition processes that are well known to those skilled in the art. For example, the at least one layer of the interfacial dielectric material 16 can be formed by atomic layer deposition (ALD), plasma enhanced atomic layer deposition (PE-ALD), chemical vapor deposition (CVD), plasma enhanced chemical vapor deposition (PECVD), evaporation, molecular beam epitaxy, photo chemical vapor deposition (including laser/UV photo assisted CVD), and spin-on dielectric processes.

In the various processes mentioned above, suitable precursors can be used in forming the at least one layer of the interfacial dielectric material 16. The precursors that can be used may include a single precursor in which at least one of the atoms of the interfacial dielectric material is present, or multiple precursors can be employed in forming the at least one layer of the interfacial dielectric material 16.

In one embodiment of the invention, and when the at least one layer of the interfacial dielectric material 16 is hexagonal boron nitride, ALD or PE-ALD is typically employed in forming the interfacial dielectric material. In this particular embodiment of the invention, the hexagonal boron nitride can be formed from at least one precursor that includes boron and optionally nitrogen. In another embodiment of the invention and when hexagonal boron nitride is employed as the at least one layer of the interfacial dielectric material 16, the hexagonal boron nitride is formed from a first precursor that includes boron and a second precursor that includes nitrogen. In embodiments of the invention in which hexagonal boron nitride is formed, the precursor(s) includes borazine, vinyl borazine, trivinylborazine, trimethyl borazine, trimethyl trivinyl borazine, tris(dimethylamino) borane, B₂H₆, B₁₀H₁₄ and a boron hydride cluster. In some embodiments, nitrogen or a nitrogen-containing material can be added as a second precursor to form the hexagonal boron nitride material.

It is observed that the presence of the at least one layer of the interfacial dielectric material 16 provides an enhanced bonding interface to the underlying carbon-based material 12 which is not present when the at least one layer of the interfacial dielectric material 16 is not formed on the carbon-based material 12. The enhanced bonding interface that is achieved when the at least one layer of the interfacial dielectric material 16 is present on the carbon-based material 12 increases the bond strength of other material layers to the carbon-based material 12, which is not obtainable when the at least one layer of the interfacial dielectric material 16 is not present on the carbon-based material 12. In some embodiments of the invention, a greater than 100% increase in bonding strength between the carbon-based dielectric material 12 that includes the at least one layer of the interfacial dielectric material 16 and an overlying material layer, i.e., dielectric material and/or conductive material) can be obtained as compared to the same structure that does not include the at least one layer of the interfacial dielectric material 16. In fact, without the presence of the at least one layer of the interfacial dielectric material, most dielectrics and/or metals will not be able to adhere or bond with graphene.

Referring now to FIG. 3, there is illustrated the structure of FIG. 2 after forming at least one other material layer 18 on an upper surface of the at least one layer of the interfacial dielectric material 16. The at least one other material 18 that can be employed in the present invention includes at least one layer of a dielectric material, at least one layer of a conductive material, or a combination of at least one layer of a dielectric material and at least one layer of a conductive material. In such a combination, the at least one layer of dielectric material can be located atop, or below, typically below, the at least one layer of dielectric material. In other embodiments of the invention, the at least one other material layer 18 includes at least one layer of dielectric material having at least one layer of conductive material embedded therein.

Examples of dielectric materials that can be employed as the at least one other material layer 18 include any insulating material such as for example, an oxide, a nitride, an oxynitride or a multilayered stack thereof. In one embodiment of the invention, the dielectric material that can be employed as the at least one other material layer 18 includes a semiconductor oxide, a semiconductor nitride or a semiconductor oxynitride. In another embodiment of the invention, the dielectric material that can be employed as the at least one other material layer 18 includes a dielectric metal oxide or mixed metal oxide having a dielectric constant that is greater than the dielectric constant of silicon oxide, e.g., 3.9. Typically, the dielectric material that can be employed as the at least one other material layer 18 has a dielectric constant greater than 4.0, with a dielectric constant of greater than 8.0 being more typical. Such dielectric materials are referred to herein as a high k dielectric. Exemplary high k dielectrics include, but are not limited to HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Multilayered stacks of these high k materials can also be employed as the at least one other material layer 18. Each value of x is independently from 0.5 to 3 and each value of y is independently from 0 to 2.

The thickness of the dielectric material that can be employed as the at least one other material layer 18 may vary depending on the technique used to form the same. Typically, the dielectric material that can be employed as the at least one other material layer 18 has a thickness from 1 nm to 10 nm, with a thickness from 2 nm to 5 nm being more typical. When a high k dielectric is employed as the dielectric material, the high k dielectric can have an effective oxide thickness on the order of, or less than, 1 nm.

The dielectric material that can be employed as the at least one other material layer 18 can be formed by methods well known in the art. In one embodiment of the invention, the dielectric material that can be employed as the at least one other material layer 18 can be formed by a deposition process such as, for example, chemical vapor deposition (CVD), thermal or plasma enhanced chemical vapor deposition (PECVD), physical vapor deposition (PVD), molecular beam deposition (MBD), pulsed laser deposition (PLD), liquid source misted chemical deposition (LSMCD), and atomic layer deposition (ALD). Alternatively, the dielectric material employed as layer 18 can be formed by a thermal process such as, for example, thermal oxidation and/or thermal nitridation.

In the embodiments in which the at least one other material layer 18 includes a conductive material, the conductive material can include any conductive material including, but not limited to polycrystalline silicon, polycrystalline silicon germanium, an elemental metal, (e.g., tungsten, titanium, tantalum, aluminum, nickel, ruthenium, palladium and platinum), an alloy of at least one elemental metal, an elemental metal nitride (e.g., tungsten nitride, aluminum nitride, and titanium nitride), an elemental metal silicide (e.g., tungsten silicide, nickel silicide, and titanium silicide) and multilayered combinations thereof. In one embodiment, the conductive material that can be employed as layer 18 can be comprised of an nFET metal gate. In another embodiment, the conductive material that can be employed as layer 18 can be comprised of a pFET metal gate. In a further embodiment, the conductive material that can be employed as layer 18 can be comprised of polycrystalline silicon. The polysilicon conductive material can be used alone, or in conjunction with another conductive material such as, for example, a metal conductive material and/or a metal silicide material.

The conductive material that is employed as layer 18 can be formed utilizing a conventional deposition process including, for example, chemical vapor deposition (CVD), plasma enhanced chemical vapor deposition (PECVD), evaporation, physical vapor deposition (PVD), sputtering, chemical solution deposition, atomic layer deposition (ALD) and other like deposition processes. When Si-containing materials are used as the conductive material, the Si-containing materials can be doped within an appropriate impurity by utilizing either an in-situ doping deposition process or by utilizing deposition, followed by a step such as ion implantation or gas phase doping in which the appropriate impurity is introduced into the Si-containing material. When a metal silicide is formed, a conventional silicidation process is employed.

The as-deposited conductive material typically has a thickness from 1 nm to 100 mm, with a thickness from 3 nm to 30 nm being even more typical.

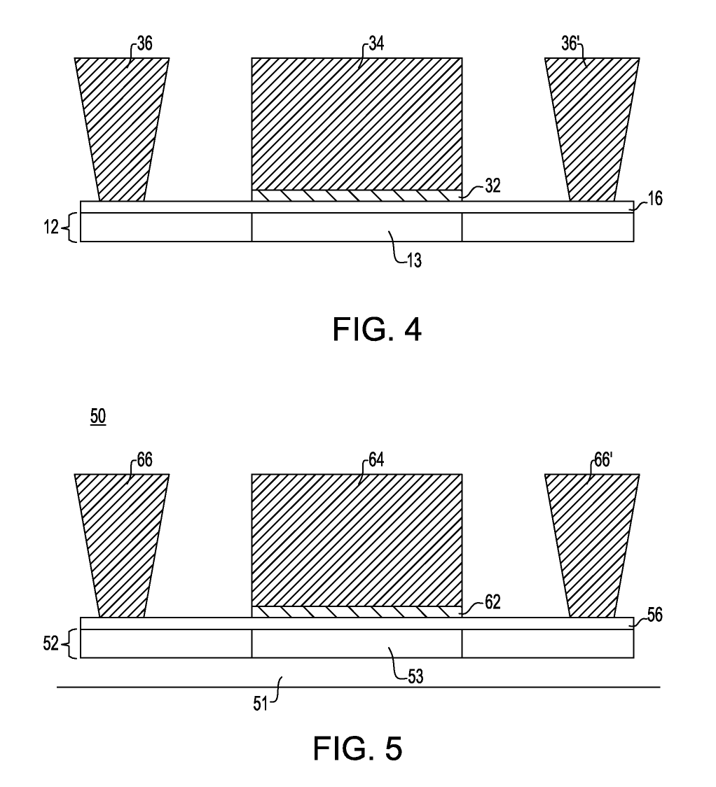

Referring now to FIG. 4, there is illustrated one type of electronic device that can be fabricated using the above described processing techniques in conjunction with any conventional FET process flow, including a replacement gate process. In some embodiments the FET process that can be used includes deposition of the various material layers, lithography and etching.

In particular, FIG. 4 illustrates an electronic device 30 that includes a carbon-based material 12, wherein a portion of the carbon-based material defines a device channel 13. At least one layer of an interfacial dielectric material 16 is located on an upper surface of the device channel 13. As mentioned above, the at least one layer of interfacial dielectric material 16 has an short-range crystallographic bonding structure that is the same as that of the carbon-based material 12. At least one layer of a dielectric material 32 is located on an uppermost surface of the at least one layer of interfacial dielectric material 16, and at least one layer of a conductive material 34 is located on an uppermost surface of the at least one layer of dielectric material 32. It is noted that the dielectric material 32 and the conductive material 34 mentioned within this particular embodiment of the present are composed of one of the dielectric materials and conductive materials mentioned above for layer 18 in FIG. 3. Also, the dielectric material 32 and the conductive material 34 are formed utilizing one of the techniques mentioned above in forming the dielectric material and conductive material for layer 18.

The electronic device 30 shown in FIG. 4 further includes at least two regions 36, 36′ that make electrical contact to portions of the carbon-based material 12 that are adjacent to the device channel 13. The two regions 36, 36′ are the source/drain regions of the electronic device 30 and they include one of the conductive materials mentioned above for layer 18. In one embodiment, the at least two regions 36, 36′ are composed of graphene or carbon based materials. The at least two regions 36, 36′ are formed by deposition, lithography and etching. In one embodiment (not shown), the at least two regions 36, 36′ are in direct contact with the carbon-based material 12. Such a device is achieved by removing portions of the at least one layer of interfacial dielectric material 16 by etching. In another embodiment, the at least two regions 36, 36′ are in direct contact with a portion of the at least one layer of interfacial dielectric material 16.

Referring now to FIG. 5, there is illustrated a second type of electronic device that can be fabricated using the above basic processing techniques in conjunction with a process flow that is modified from the process used to fabricate the device of FIG. 4. In some embodiments the process that can be used to fabricate the structure shown in FIG. 5 includes deposition of the various material layers, lithography and etching. Specifically, FIG. 5 illustrates a back gated type FET, also known as a dual gate FET device. In FIG. 5, electronic device 50 includes a carbon-based material 52, wherein a portion of the carbon-based material defines a device channel 53. The back gate layer is labeled 51, and this layer may be patterned or may be present throughout an array of devices as a blanket layer. At least one layer of an interfacial dielectric material 56 is located on an upper surface of the device channel 53. As mentioned above, the at least one layer of interfacial dielectric material 56 has a crystallographic bonding structure that is the same or at least the same short-range crystallographic bonding structure as that of the carbon-based material 52. At least one layer of a dielectric material 62 is located on an uppermost surface of the at least one layer of interfacial dielectric material 56, and at least one layer of a conductive material 64 is located on an uppermost surface of the at least one layer of dielectric material 62. It is noted that the dielectric material 62 and the conductive material 64 mentioned within this particular embodiment of the present are composed of one of the dielectric materials and conductive materials mentioned above for layer 18 in FIG. 3. Also, the dielectric material 62 and the conductive material 64 are formed utilizing one of the techniques mentioned above in forming the dielectric material and conductive material for layer 18.

The electronic device 50 shown in FIG. 5 further includes at least two regions 66, 66′ that make electrical contact to portions of the carbon-based material 52 that are adjacent to the device channel 53. The two regions 66, 66′ are the source/drain regions of the electronic device 50 and they include one of the conductive materials mentioned above for layer 18. In one embodiment, the at least two regions 66, 66′ are composed of graphene or a carbon based material. The at least two regions 66, 66′ are formed by deposition, lithography and etching. In one embodiment (not shown), the at least two regions 66, 66′ are in direct contact with the carbon-based material 52. Such a device is achieved by removing portions of the at least one layer of interfacial dielectric material 56 by etching. In another embodiment, the at least two regions 66, 66′ are in direct contact with a portion of the at least one layer of interfacial dielectric material 56.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A semiconductor structure comprising:
at least one layer of an interfacial dielectric material located on an upper surface of a carbon-based material, wherein said at least one layer of interfacial dielectric material has a short-range crystallographic bonding structure that is the same as that of said carbon-based material.

2. The semiconductor structure of claim 1 wherein said carbon-based material has a hexagonal crystallographic bonding structure.

3. The semiconductor structure of claim 2 wherein said carbon-based material is graphene, graphite or a carbon nanotube.

4. The semiconductor structure of claim 2 wherein said at least one layer of interfacial dielectric material is boron nitride, silicon carbide, carbon boron nitride, silicon boron nitride or other dielectrics with a hexagonal crystallographic bonding structure.

5. The semiconductor structure of claim 4 wherein said at least one layer of interfacial dielectric material is hexagonal boron nitride.

6. The semiconductor structure of claim 1 further comprising at least one layer of a dielectric material located on an uppermost surface of said at least one layer of interfacial dielectric material.

7. The semiconductor structure of claim 6 wherein said at least one layer of dielectric material comprises an oxide, nitride, oxynitride, metal oxide, or mixed metal oxide.

8. The semiconductor structure of claim 1 further comprising at least one layer of a conductive material located on an uppermost surface of said at least one layer of interfacial dielectric material.

9. The semiconductor structure of claim 8 wherein said at least one layer of the conductive material comprises a Si-containing conductive material, a conductive metal, a conductive metal oxide, a conductive metal nitride, or a conductive metal silicide.

10. An electronic device comprising:
a carbon-based material, wherein a portion of said carbon-based material defines a device channel;
at least one layer of an interfacial dielectric material located on an upper surface of said device channel, wherein said at least one layer of interfacial dielectric material has a short-range crystallographic bonding structure that is the same as that of said carbon-based material;
at least one layer of a dielectric material located on an uppermost surface of said at least one layer of interfacial dielectric material; and
at least one layer of a conductive material located on an uppermost surface of said at least one layer of dielectric material.

11. The electronic device of claim 10 further comprising at least two regions making electrical contact to portions of said carbon-based material adjacent to said device channel.

12. The electronic device of claim 10 wherein said carbon-based material is graphene and said at least one layer of interfacial dielectric material is comprised of a dielectric material having a hexagonal crystallographic bonding structure.

13. The electronic device of claim 10 wherein said at least one layer of interfacial dielectric material is hexagonal boron nitride.

14. The electronic device of claim 10 wherein said at least one layer of dielectric material comprises a semiconductor oxide, semiconductor nitride, semiconductor oxynitride, metal oxide, or mixed metal oxide.

15. The electronic device of claim 14 wherein said at least one layer of dielectric material comprises a semiconductor oxide and a metal oxide having a dielectric constant that is greater than silicon oxide.

16. The electronic device of claim 10 wherein said at least one layer of conductive material comprises a Si-containing conductive material, a conductive metal, a conductive metal oxide, a conductive metal nitride, or a conductive metal silicide.

17. The electronic devices of claim 10 further comprising a conductor under the carbon-based material channel, said conductor acting as a back gate.

18. A method of forming a semiconductor structure comprising:
forming at least one layer of an interfacial dielectric material on an upper surface of a carbon-based material, wherein said at least one layer of interfacial dielectric material has a short-range crystallographic bonding structure that is the same as that of said carbon-based material.

19. The method of claim 18 wherein said forming the at least one layer of the interfacial dielectric material includes atomic layer deposition, plasma enhanced atomic layer deposition, chemical vapor deposition, plasma enhanced chemical vapor deposition, evaporation, molecular beam epitaxy, photo chemical vapor deposition, and a spin-on process.

20. The method of claim 18 wherein said carbon-based material is graphene and said interfacial dielectric material is boron nitride.

21. The method of claim 20 wherein said boron nitride is formed from at least one precursor that includes boron and nitrogen in one precursor, or boron with another nitrogen source.

22. The method of claim 21 wherein said at least one precursor includes borazine, vinyl borazine, trivinylborazine, trimethyl borazine, trimethyl trivinyl borazine, tris(dimethylamino) borane, B₂H₆, B₁₀H₁₄ and a boron hydride cluster.

23. The method of claim 20 wherein said boron nitride is formed from a first precursor that includes boron and a second precursor that includes nitrogen.

24. The method of claim 18 further comprising forming at least one layer of a dielectric material on an uppermost surface of said at least one layer of interfacial dielectric material.

25. The method of claim 18 further comprising forming at least one layer of a conductive material on an uppermost surface of said at least one layer of interfacial dielectric material.

26. The method of claim 18 further comprising forming at least one layer of a dielectric material on an uppermost surface of said at least one layer of interfacial dielectric material, and forming at least one layer of a conductive material on an uppermost surface of said at least one layer of dielectric material.
